(19) United States
(12) Patent Application Publication
(10) Pub. No.: US 2008/0252341 A1
(43) Pub. Date: Oct. 16, 2008

(54) CLOCK SIGNAL DISTRIBUTION CIRCUIT AND INTERFACE APPARATUS USING THE SAME

(75) Inventors: Yong-Ju Kim, Ichon (KR); Kun-Woo Park, Ichon (KR); Jong-Woon Kim, Ichon (KR); Hee-Woong Song, Ichon (KR); Ic-Su Oh, Ichon (KR); Hyung-Soo Kim, Ichon (KR); Tae-Jin Hwang, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMINCONDUCTOR, INC., Ichon (KR)

(21) Appl. No.: 11/962,969

(22) Filed: Dec. 21, 2007

(30) Foreign Application Priority Data
Apr. 13, 2007 (KR) 10-2007-0036332

(51) Int. Cl. H03L 7/06

(52) U.S. Cl. 327/157; 327/158

(57) ABSTRACT

A clock signal distribution circuit comprises a voltage control and distribution circuit configured to change a delay of a received clock signal in response to a control voltage and to generate a distributed clock signal, and control voltage generation circuit configured to generate the control voltage using a phase difference between received data and the distributed clock signal.

### CROSS-REFERENCES TO RELATED APPLICATION

The present application claims priority under 35 U.S.C. 119(a) to Korean application number 10-2007-36332, filed on Apr. 13, 2007, in the Korean Patent Office, which is incorporated by reference in its entirety as if set forth in full.

### BACKGROUND OF THE INVENTION

1. Technical Field

The embodiments described herein relate to a semiconductor technology, and more particularly, to a clock signal distribution circuit that outputs a clock signal and an interface apparatus using the same.

2. Related Art

The data transmission and reception speed has exceeded a Gbps level for conventional interface technology, for example, between a memory controller such as a CPU (central processing unit) or a GPU (graphic processing unit) and a DRAM (dynamic random access memory). In order to realize a semiconductor memory interface capable of such high speed transmission and reception of data, it is necessary to suppress the generation of clock jitter and to maximize the setup and hold margin of a receiver being used to receive the data.

In a conventional device, data and a clock signal are transmitted through different channels in the transmission interface apparatus used by, e.g., a GPU. The data and the clock signal are received by a reception interface apparatus, which is interfaced with, e.g., a DRAM and are transmitted using a predefined signal processing procedure to a core block within the DRAM that has memory cells and data processing circuits.

In order for the DRAM to accurately receive the data, any delay affecting the data and the clock signal must be substantially the same. However, the transmission and reception interface apparatus exhibit static skew. That is to say, there exist a delay due to signal processing in the clock signal distribution circuit of the DRAM, and a delay due to a mismatch that can be introduced by the printed circuit board (PCB) on which the circuit is laid out. The data and the clock signal are skewed as a result.

In order to eliminate the static skewresulting from the clock signal distribution circuit and/or the printed circuit board can be compensated in advance in the transmission interface apparatus and/or the GPU.

In addition to the above-described static skew, another skew occurs in actual dynamic conditions due to a jitter caused by temperature variation or source voltage noise. However, since the de-skew circuit provided via the transmission system, i.e., the transmission interface apparatus and GPU, cannot properly correct this skew, the data transmission speed is decreased, and data transmission and reception reliability is diminished.

### SUMMARY

A clock signal distribution circuit that can maintain a data transmission speed and data transmission and reception reliability, and an interface apparatus using the same, are described herein.

According to one aspect, there is provided a clock signal distribution circuit comprising a voltage control and distribution circuit configured to change a delay of a received clock signal in response to a control voltage and to generate a distributed clock signal, and a control voltage generation circuit configured to generate the control voltage using a phase difference between the received data and the distributed clock signal.

According to another aspect, there is provided an interface apparatus comprising a receiving circuit configured to receive data and a clock signal, a loop circuit configured to generate a control voltage depending upon a phase difference between the received data and clock signal and to correct a delay of the clock signal using the control voltage, and a latch configured to latch data in response to the corrected clock signal corrected in the loop circuit.

According to still another aspect, there is provided an interface apparatus comprising a first interface circuit configured to transmit data and a clock signal and a second interface circuit configured to generate a control voltage depending upon a phase difference between the transmitted data and clock signal, to correct a delay of the clock signal using the control voltage, and to input data to a core block in response to the delay-corrected clock signal.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a block diagram illustrating a data communication interface in accordance with one embodiment;

FIG. 2 is a circuit diagram of a clock signal distribution circuit that can be included in the interface shown FIG. 1; and

FIG. 3 is a circuit diagram of a voltage control and distribution unit that can be included in the interface shown in FIG. 1.

### DETAILED DESCRIPTION

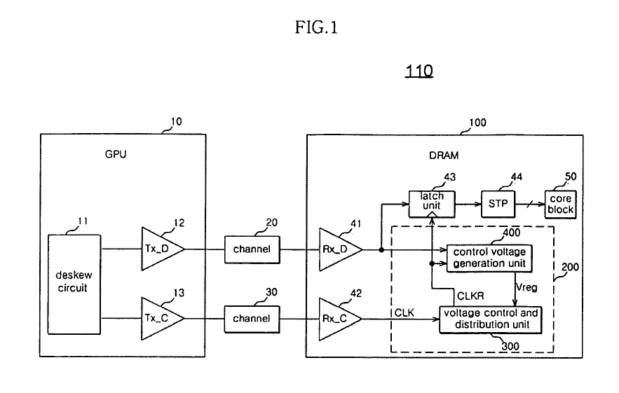

FIG. 1 is a diagram illustrating an example circuit 110 that includes a data communication interface according to one embodiment. As can be seen in reference to FIG. 1, the communication interface can comprise a first interface apparatus included in or interfaced with, e.g., a GPU 10. The first interface apparatus can be referred to as a transmission interface apparatus and can be configured to transmit data and a clock signal through respective channels 20 and 30.

The communication interface can also include a second interface apparatus included in or interfaced with, e.g., a DRAM 100. The second interface apparatus can be referred to as a reception interface apparatus and can be configured to receive the data and the clock signal and, after implementing a predefined signal processing procedure, e.g., to compensate for phase difference in the received signals, to transmit the data and the clock signal to a core block 50, which can include memory cells and data processing circuits.

The transmission interface apparatus can comprise a de-skew circuit 11, a data transmitter (Tx_D) 12, and a clock signal transmitter (Tx_C) 13. In certain embodiments, the de-skew circuit 11, or at least the de-skew function can be included in the reception interface apparatus as will be described later in detail.

As illustrated, the reception interface apparatus can comprise a data receiver (Rx_D) 41, a clock signal receiver (Rx_C) 42, a latch unit 43, a serial to parallel converter (STP) 44, and a clock signal distribution circuit 200. In addition, the DRAM 100 can comprise the core block 50, which has memory cells and various signal processing circuits.

The data generated by the de-skew circuit 11 and transmit by the data transmitter (Tx_D) 12 over channel 20 can be serial data and thus, receiver 41 can be configured to receive the serial data. The latch unit 43 can comprise a plurality of latches, i.e., flip-flops for each of the serial data bits. The serial to parallel converter 44 can then be configured to convert the serial data into parallel data and transmit the converted parallel data to the core block 50.

The clock signal distribution circuit 200 can be configured to distribute the received clock signal ‘CLK’ and to output a distributed clock signal ‘CLKR’. The clock signal distribution circuit 200 can be further configured to correct the delay of the distributed clock signal ‘CLKR’ in real time using a control voltage ‘Vreg’, which is generated based on the phase difference between the data and the distributed clock signal ‘CLKR’.

The clock signal distribution circuit 200 can comprise a voltage control and distribution unit 300 configured to distribute the received clock signal ‘CLK’ with a delay based on the control voltage ‘Vreg’, and a control voltage generation unit 400 that can be configured to generate the control voltage ‘Vreg’ using the phase difference between the data and the distributed clock signal ‘CLKR’.

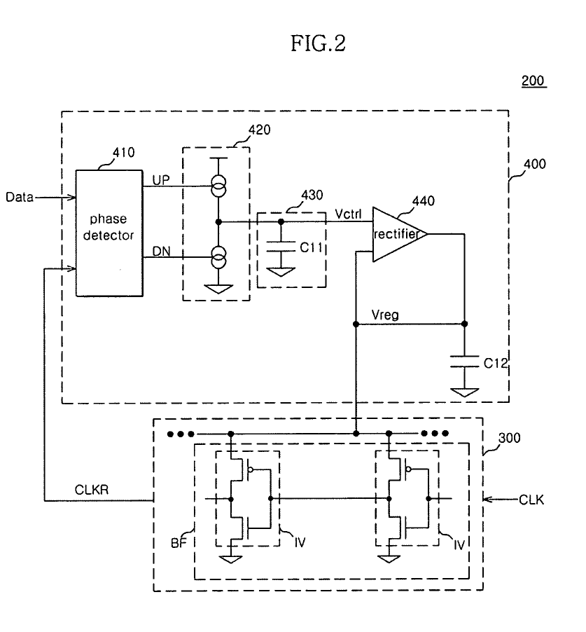

FIG. 2 is a diagram illustrating the clock distribution circuit 200 in more detail. Referring to FIG. 2, it can be seen that the control voltage generation unit 400 can comprise a phase detector 410, a charge pump 420, a filter 430, a rectifier 440, and a capacitor C12. The phase detector 410 can be configured to compare the phase of the data ‘Data’ with the phase of the distributed clock signal ‘CLKR’ and generate phase difference detection signals ‘UP’ and ‘DN’ based on the comparison. For example, if the phase difference between the data ‘Data’ and the distributed clock signal ‘CLKR’ is less than a preset value, then the phase detector 410 can be configured to output the up signal ‘UP’, and if the phase difference between the data ‘Data’ and the distributed clock signal ‘CLKR’ is greater than the preset value, then the phase detector 410 can be configured to output the down signal ‘DN’.

The charge pump 420 can be configured to charge or discharge a capacitor C11, which is used as the filter 430, in response to the up signal ‘UP’ or the down signal ‘DN’, such that a reference voltage ‘Vctrl’ corresponding to the voltage level of the capacitor C11 is generated as an input to rectifier 440. The filter 430 can be configured to not only generate the reference voltage ‘Vctrl’, but to also filter noise components on the ‘UP’ and ‘DN’ signals, for example, high frequency components produced by source voltage noise.

The rectifier 440 in conjunction with the capacitor C12 generates the control voltage ‘Vreg’ output. The rectifier 440 can be configured to change the control voltage ‘Vreg’ based on changes in the reference voltage ‘Vctrl’.

The voltage control and distribution unit 300 can comprise a plurality of buffers BF each of which can be composed of a pair of inverters IV. The buffer BF can be supplied with the control voltage ‘Vreg’ as a variable operating voltage. The inverter IV, which constitutes the buffer BF, has an input and output transition timing that is shortened when the operating voltage is high and is extended as the operating voltage becomes low. In other words, the buffer BF contents are changed in accordance with a signal processing delay depending upon the operating voltage.

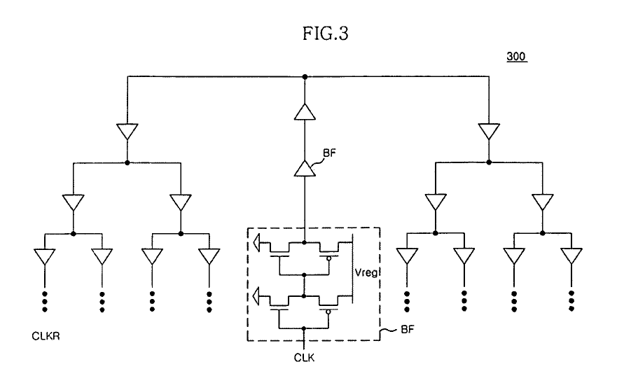

As shown in FIG. 3, the voltage control and distribution unit 300 can include a connection structure such that the clock signal ‘CLK’ is divided after passing through one or more buffers BF, and the divided output is input to another buffer BF and then divided and output again. The number of divisions and the number of buffers BF can change depending on the requirements of a particular implementation.

It will be understood given the forgoing description that the phase detector 410, the charge pump 420, the filter 430, the rectifier 440, the capacitor C12, and the voltage control and distribution unit 300 form a negative feedback loop.

The operation of the clock signal distribution circuit 200 will now be described in detail. First, the data and the clock signal ‘CLK’ can be transmitted from the data transmitter 12 and the clock signal transmitter 13 of the GPU 10 through the respective channels 20 and 30. The transmitted data and clock signal ‘CLK’ can be respectively received by the data receiver 41 and the clock signal receiver 42.

The data and the clock signal ‘CLK’ can have a phase difference of 90°. The clock signal ‘CLK’ can have two phases of 0° and 180°.

The latch unit 43 can be configured to sample the data twice, once at each of the two respective phases of 0° and 180° of the clock signal ‘CLK’ and then output the sampled data to the serial to parallel converter 44. The serial to parallel converter 44 can be configured to output the serial data sampled by the latch unit 43 as parallel data with a timing that allows the parallel data to be recorded on the core block 50.

In order to allow the data to be precisely sampled by the latch unit 43, the two phases of the clock signal ‘CLK’ must have phase differences of 90° and 270° with the data. However, in actuality, due to the variation of temperature and of source voltage noise, the phase differences between the clock signal ‘CLK’ and the data will not always correspond to 90° and 270°. The clock signal distribution circuit 200 can be configured to compensate for the error so that the phase differences between the clock signal ‘CLK’ and the data correspond to 90° and 270°. This will be described below in detail.

The phase detector 410 can be configured to compare the phases of the data ‘Data’ and the distributed clock signal ‘CLKR’. If the phase difference between the data ‘Data’ and the distributed clock signal ‘CLKR’ is less than a preset value, the phase detector 410 can be configured to output the up signal ‘UP’, and if the phase difference between the data ‘Data’ and the distributed clock signal ‘CLKR’ is greater than the preset value, the phase detector 410 can be configured to output the down signal ‘DN’.

If the up signal ‘UP’ is output, then the charge pump 420 charges the capacitor C11 of the filter 430, and if the down signal ‘DN’ is output, then the charge pump 420 discharges the capacitor C11.

In response to the charging and discharging of the capacitor C11, the level of the reference voltage ‘Vctrl’ is raised and lowered, which changes the out put of the rectifier 440. The output of the rectifier 440 charges capacitor C12 and can be taken as the control voltage ‘Vreg’. The rectifier 440 changes its output so that the control voltage ‘Vreg’ can be changed in conformity with the change of the reference voltage ‘Vctrl’, which will be described below.

If the reference voltage ‘Vctrl’ is raised, the rectifier 440 lowers the voltage level on the capacitor C12 through adjustment of its output so that the control voltage ‘Vreg’ is lowered. Also, if the reference voltage ‘Vctrl’ is lowered, the rectifier 440 raises the voltage level on the capacitor C12 through adjustment of its output so that the control voltage ‘Vreg’ is raised.

The voltage control and distribution unit 300 changes the signal processing delay of the respective buffers BF in response to the change of the control voltage ‘Vreg’, and distributes the received clock signal ‘CLK’ in response to the changed signal processing delay and outputs the distributed clock signal ‘CLKR’.

As the negative feedback loop, which is constituted by the phase detector 410, the charge pump 420, the filter 430, the rectifier 440, the capacitor C12, and the voltage control and distribution unit 300, operates repeatedly, the correction of the delay of the distributed clock signal ‘CLKR’ can be implemented in real time.

In the embodiments described above, the phase difference between the data and the distributed clock signal ‘CLKR’ can be kept constant at the level desired by the system, irrespective of the jitter components, which are caused by variation in temperature and the generation of source voltage noise.

The latch unit 43 can be configured to sample and latch the data when the distributed clock signal ‘CLKR’ has the phase differences of 90° and 270° with the data and then output the sampled and latched data to the serial to parallel converter 44.

The serial to parallel converter 44 can be configured to convert the serial data outputted from the latch unit 43 into parallel data and transmit the converted parallel data to the core block 50.

The core block 50 can be configured to record the parallel data in memory cells through internal signal processing circuits.

Accordingly, the data transmission speed can be maintained, as can the reliability of data transmission and reception even though temperature varies and source voltage noise is generated, since the delay of the clock signal is changed to accommodate the variation of temperature and the generation of source voltage noise and the phase difference between data and the clock signal is kept constant. Also, because the phase difference between the data and the clock signal is controlled in real time in the reception system, a de-skew circuit does not have to be included in the transmission system, making implementation of the transmission circuit easier.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A clock signal distribution circuit comprising:
a voltage control and distribution circuit configured to change a delay of a received clock signal in response to a control voltage and to output a distributed clock signal; and
a control voltage generation circuit configured to generate the control voltage using a phase difference between the received data and the distributed clock signal.

2. The clock signal distribution circuit according to claim 1, wherein the voltage control and distribution circuit comprises a plurality of buffers, and the control voltage is applied to the plurality of buffers.

3. The clock signal distribution circuit according to claim 1, wherein the control voltage generation circuit comprises:
a phase detector configured to receive the data and the distributed clock signal and to output a phase difference detection signal representing a phase difference between them;
a charge pump configured to generate a reference voltage through charging or discharging in response to the phase difference detection signal; and
a rectifier configured to change the control voltage in response to the reference voltage.

4. The clock signal distribution circuit according to claim 3, wherein the rectifier comprises an input, and wherein the rectifier is configured to receive the control voltage as a feedback signal at the rectifier input.

5. The clock signal distribution circuit according to claim 3, wherein the phase difference detection signal comprises an up signal, and wherein the phase detector is configured to output the up signal when the phase difference between the data and the distributed clock signal less than a preset value.

6. The clock signal distribution circuit according to claim 5, wherein the phase difference detection signal comprises a down signal, and wherein the phase detector is configured to output the down signal when the phase difference between the data and the distributed clock signal greater than a preset value.

7. An interface apparatus comprising:
a receiving circuit configured to receive data and a clock signal;
a loop circuit configured to generate a control voltage based on a phase difference between the received data and clock signal, and to correct a delay of the clock signal using the control voltage; and
a latch configured to latch data in response to the clock signal corrected in the loop circuit.

8. The interface apparatus according to claim 7, wherein the loop circuit comprises:
a voltage control and distribution circuit configured to change a delay of the received clock signal in response to the control voltage and to output a distributed clock signal; and
a control voltage generation circuit configured to generate the control voltage using a phase difference between the data and the distributed clock signal.

9. The interface apparatus according to claim 8, wherein the voltage control and distribution circuit comprises a plurality of buffers, and the control voltage is applied to the plurality of buffers.

10. The interface apparatus according to claim 8, wherein the control voltage generation circuit comprises:
a phase detector configured to receive the data and the distributed clock signal and output a phase difference detection signal representing a phase difference between them;
a charge pump configured to generate a reference voltage through charging or discharging in response to the phase difference detection signal; and
a rectifier configured to change the control voltage in response to the reference voltage.

11. The interface apparatus according to claim 10, wherein the rectifier comprises and input, and wherein the rectifier is configured to receive the control voltage as a feedback signal at the rectifier input.

12. The interface apparatus according to claim 10, wherein the phase difference detection signal comprises an up signal, and wherein the phase detector is configured to output the up signal when the phase difference between the data and the distributed clock signal less than a preset value.

13. The interface apparatus according to claim 12, wherein the phase difference detection signal comprises a down signal, and wherein the phase detector is configured to output the down signal when the phase difference between the data and the distributed clock signal greater than a preset value.

14. An interface apparatus comprising:
a first interface circuit configured to transmit data and a clock signal; and
a second interface circuit configured to generate a control voltage depending upon a phase difference between the transmitted data and clock signal, correct a delay of the clock signal using the control voltage, and input data to a core block in response to the delay-corrected clock signal.

15. The interface apparatus according to claim 14, wherein the first interface circuit comprises:
a data transmission circuit configured to transmit the data; and
a clock signal transmission circuit configured to transmit the clock signal.

16. The interface apparatus according to claim 15, further comprising:
a de-skew circuit configured to correct a phase difference between the data and the clock signal and transmit the data to the data transmission circuit and the clock signal to the clock signal transmission circuit.

17. The interface apparatus according to claim 14, wherein the second interface circuit comprises:
a receiving circuit configured to receive data and a clock signal;
a loop circuit configured to generate a control voltage depending upon a phase difference between the received data and clock signal and to correct a delay of the clock signal using the control voltage; and
a latch configured to latch data in response to the clock signal corrected in the loop circuit.

18. The interface apparatus according to claim 17, wherein the loop circuit comprises:
a voltage control and distribution circuit configured to change a delay of the received clock signal in response to the control voltage and to generate a distributed clock signal; and
a control voltage generation circuit configured to generate the control voltage using a phase difference between the data and the distributed clock signal.

19. The interface apparatus according to claim 18, wherein the voltage control and distribution circuit comprises a plurality of buffers, and the control voltage is applied to the plurality of buffers.

20. The interface apparatus according to claim 18, wherein the control voltage generation circuit comprises:
a phase detector configured to receive the data and the distributed clock signal and to output a phase difference detection signal representing a phase difference between them;
a charge pump configured to generate a reference voltage through charging or discharging in response to the phase difference detection signal; and
a rectifier for changing the control voltage in response to the reference voltage.

21. The interface apparatus according to claim 20, wherein the rectifier comprises and input, and wherein the rectifier is configured to receive the control voltage as a feedback signal at the rectifier input.

22. The interface apparatus according to claim 20, wherein the phase difference detection signal comprises an up signal, and wherein the phase detector is configured to output the up signal when the phase difference between the data and the distributed clock signal less than a preset value.

23. The interface apparatus according to claim 22, wherein the phase difference detection signal comprises a down signal, and wherein the phase detector is configured to output the down signal when the phase difference between the data and the distributed clock signal greater than a preset value.
